(19) United States
(12) Patent Application Publication
(10) Pub. No.: US 2024/0063203 A1
(43) Pub. Date: Feb. 22, 2024

(54) PACKAGE ARCHITECTURES WITH GLASS CORES FOR THICKNESS REDUCTION AND 3D INTEGRATION

(71) Applicant: Intel Corporation, Santa Clara, CA (US)

(72) Inventors: Brandon C. MARIN, Gilbert, AZ (US); Ravindranath V. MAHAJAN, Chandler, AZ (US); Srinivas V. PIETAMBARAM, Chandler, AZ (US); Gang DUAN, Chandler, AZ (US); Suddhasattwa NAD, Chandler, AZ (US); Jeremy D. ECTON, Gilbert, AZ (US); Navneet SINGH, Bangalore (IN); Sushil PADMANABHAN, Kerala (IN); Samarth ALVA, Bangalore (IN)

(21) Appl. No.: 17/889,962

(22) Filed: Aug. 17, 2022

(51) Int. Cl. H01L 25/18; H01L 23/15; H01L 23/538; H01L 23/48; H01L 21/48; H01L 25/00; H01L 21/56

(52) U.S. Cl. CPC H01L 25/18; H01L 23/15; H01L 23/5383; H01L 23/481; H01L 23/5384; H01L 21/486; H01L 21/4857; H01L 25/50; H01L 21/56

(57) ABSTRACT

Embodiments disclosed herein include electronic packages. In an embodiment, the electronic package comprises a substrate, where the substrate comprises glass, and buildup layers over the first substrate. In an embodiment, a first die is over the buildup layers, a second die is over the buildup layers and adjacent to the first die, and where conductive routing in the buildup layers electrically couples the first die to the second die.

### TECHNICAL FIELD

Embodiments of the present disclosure relate to electronic packages, and more particularly to electronic packages with glass cores to enable thickness reductions and more assembly friendly 3D integration of components.

### BACKGROUND

In advanced packaging applications, multiple dies (tiles) are provided on the package substrate and communicatively coupled together. This allows for advanced scaling without worrying about yield issues that arise with large area dies. In many instances, the individual dies are communicatively coupled together using embedded bridge architectures. In such architectures, a bridge die (e.g., a silicon bridge) comprises high density routing in order to provide small line/space interconnects only where needed in the electronic package. However, as the number of bridge dies needed for a given architecture increases, yield issues become more prevalent. The need to properly align the many different bridges and/or deal with bump thickness variation (BTV) problems may result in low yields for the electronic packages.

### BRIEF DESCRIPTION OF THE DRAWINGS

FIG. 1 is a cross-sectional illustration of an electronic package with a glass core that enables high density routing to couple multiple dies together, in accordance with an embodiment.

FIGS. 2A-2E are cross-sectional illustrations depicting a process for forming an electronic package with a glass core that enables high density routing, in accordance with an embodiment.

FIG. 3 is a cross-sectional illustration of an electronic package with a glass core that enables high density routing in accordance with an additional embodiment.

FIGS. 4A-4D are cross-sectional illustrations depicting a process for forming an electronic package with a glass core that enables high density routing, in accordance with an additional embodiment.

FIG. 5 is a cross-sectional illustration of an electronic package with a glass core and pads in order to implement wire bonding between electronic packages, in accordance with an embodiment.

FIG. 6A is a cross-sectional illustration of an electronic package with a glass core with underlying memory dies, in accordance with an embodiment.

FIG. 6B is a cross-sectional illustration of an electronic system with a glass core and underlying memory dies that are inserted into a cavity in a board, in accordance with an embodiment.

FIGS. 7A-7C are cross-sectional illustration depicting a process for forming an electronic package with a glass core and underlying memory dies, in accordance with an embodiment.

FIG. 8A is a cross-sectional illustration of an electronic package with a glass core and an embedded bridge, in accordance with an embodiment.

FIG. 8B is a cross-sectional illustration of an electronic system with a glass core, an embedded bridge, and memory dies that are inserted into a cavity in a board, in accordance with an embodiment.

FIG. 9 is a cross-sectional illustration of an electronic package that comprises a glass core with high density routing, in accordance with an embodiment.

FIG. 10 is a cross-sectional illustration of an electronic package that comprises a glass core with a cavity for accommodating a plurality of memory dies, in accordance with an embodiment.

FIG. 11 is a cross-sectional illustration of an electronic package that includes high density routing without the presence of a glass core, in accordance with an embodiment.

FIGS. 12A-12F are cross-sectional illustrations depicting a process for forming an electronic package with high density routing using a glass carrier substrate, in accordance with an embodiment.

FIG. 13 is a cross-sectional illustration of an electronic system with a package substrate that includes a glass core that is coupled to a board, in accordance with an embodiment.

FIG. 14 is a schematic of a computing device built in accordance with an embodiment.

### EMBODIMENTS OF THE PRESENT DISCLOSURE

Described herein are electronic packages with glass cores to enable thickness reductions and more assembly friendly 3D integration of components, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, existing solutions to communicatively couple die tiles together are limited. As the number of die tiles increase, the number of embedded bridges also increases. The ability to properly assemble the electronic package increases in difficulty with the increasing number of embedded bridges. Accordingly, embodiments disclosed herein include electronic packages that utilize a glass core configuration. The glass core enables a base that is extremely flat, stiff, and thermally stable. As such, high density routing may be fabricated directly on the glass core. That is, embedded bridges may be replaced with the high density routing on the surface of the glass core. For example, the high density routing may include trace thicknesses of approximately 2 μm or less, and trace spacings of approximately 2 μm or less. In some embodiments, the die tiles may be coupled to the high density routing using any suitable interconnect architecture. For example, hybrid bonding, solder, or micro balls may be used in order to couple the die tiles to the high density routing.

Additionally, embodiments may include through silicon vias (TSVs) that pass through the thickness of die tiles. This enables truly three dimensional (3D) integration of components. For example, the die tiles may be embedded in a mold layer and be coupled to one or more memory dies that are provided above or below the die tiles. In some instances, the memory dies may then be inserted into cavities in the underlying board. As such, the total thickness of the electronic system is reduced.

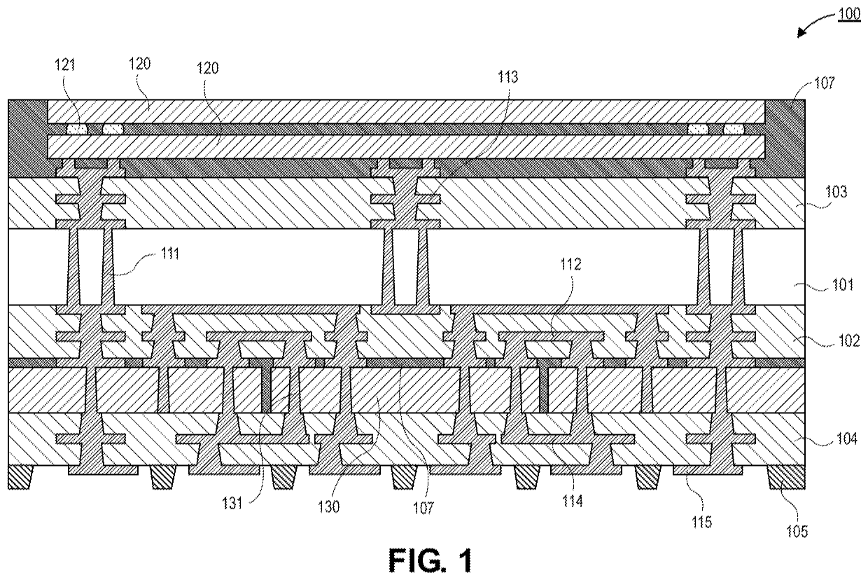

Referring now to FIG. 1, a cross-sectional illustration of an electronic package 100 is shown, in accordance with an embodiment. In an embodiment, the electronic package 100 may comprise a core 101 that comprises glass. As used herein, a core that comprises glass may refer to a core that is substantially all glass. For example, a core that comprises glass may be different than an organic core that may include glass reinforcement fibers or the like. The core 101 may have any suitable thickness. For example, the thickness of the core 101 may be approximately between 50 μm and approximately 1,000 μm. Though, thinner or thicker glass cores 101 may be used in some embodiments. As used herein, “approximately” may refer to a range of values that are within ten percent of the stated value. For example, approximately 1,000 μm may refer to a range of values between 900 μm and 1,100 μm.

In an embodiment, the core 101 may be a glass formulation that is suitable for laser assisted patterning operations. Laser assisted patterning may include a process where a laser is used to expose a region of the core 101. The laser exposure results in a change in the microstructure and/or phase of the core 101. The modified regions are then more susceptible to an etching chemistry (e.g., a wet etching chemistry) than the unexposed regions. In an embodiment, through glass vias (TGVs) 111 may be formed through the core 101 using such a process. However, it is to be appreciated that any patterning process may be used to form the TGVs 111, and embodiments are not limited to a laser assisted patterning process.

In an embodiment, the laser assisted patterning process may result in TGVs 111 that include tapered sidewalls. For example, in FIG. 1, the TGVs 111 have a trapezoidal shape with a first end that is wider than a second end. Such an embodiment is typical of a single sided patterning process. However, for thicker cores 101, a double sided patterning process may be needed. In a double sided process, the laser exposes both a top side and a bottom side of the core. In such embodiments, the cross-sectional shape of the TGVs 111 may be hourglass shaped. As used herein, an hourglass shaped cross-section may refer to a cross-section with ends that are wider than a middle (in the Z-direction) of the TGV 111. Examples of such an hourglass shaped cross-section are provided in greater detail below.

In an embodiment, the electronic package 100 may further comprise first buildup layers 102 over a surface of the core 101. The first buildup layers 102 may comprise high density routing 112. For example, the high density routing 112 may comprise pads, traces, vias, and the like. In an embodiment, high density routing 112 may refer to routing that has trace widths of 5 μm or less and trace spacings of 5 μm or less. In a particular embodiment, trace widths of 2 μm or less and trace spacings of 2 μm or less may be provided in the first buildup layers 102. The high density routing may be enabled due to the flatness of the core 101. That is, the first buildup layers 102 are fabricated on the core 101 and the advantageous flatness and dimensional stability of the core 101 enables the fabrication of high density routing 112.

In an embodiment, the high density routing 112 may be used in order to electrically couple together dies 130. For example, the high density routing 112 electrically couples the left die 130 to the center die 130, and electrically couples the right die 130 to the center die 130. The dies 130 may be die tiles in some embodiments. For example, the dies 130 may be compute dies, such as processors, graphics processors, systems on a chip (SoC), ASICs, or any other suitable type of die 130. In an embodiment, the dies 130 may be embedded in a mold layer 107. The dies 130 may be coupled to the high density routing 112 using any suitable interconnect architecture. For example, the dies 130 may be coupled to the high density routing 112 using hybrid bonding, solder, micro balls, or the like. That is, any first level interconnect (FLI) architecture may be used to couple the dies 130 to the high density routing 112. In the case of hybrid bonding, which requires very flat surfaces, the core 101 provides a flat surface in order to enable the hybrid bonding.

In an embodiment, the dies 130 may also comprise through silicon vias (TSVs) 131. While referred to as TSVs 131, it is to be appreciated that the dies 130 may comprise any suitable semiconductor, and the vias may be provided through any semiconductor material. The TSVs 131 enable true 3D interconnect architectures. For example, the bottoms of the TSVs 131 may be coupled to conductive routing 114 in third buildup layers 104. The conductive routing 114 (e.g., traces, pads, vias, etc.) may couple the dies 130 to second level interconnect (SLI) pads 115 that are surrounded by a solder resist layer 105.

In an embodiment, second buildup layers 103 may be provided over the core 101 opposite from the dies 130. The second buildup layers 103 may include conductive routing 113 (e.g., traces, pads, vias, etc.) that electrically couple the TGVs 111 to second dies 120. The second dies 120 may be memory dies. Stacks of the memory dies 120 may be electrically coupled to each other by solder balls 121 or the like. Alternatively, wire bonds (not shown) may couple the second dies 120 to the second buildup layers 103. The second dies 120 may also be embedded in a mold layer 107 in some embodiments.

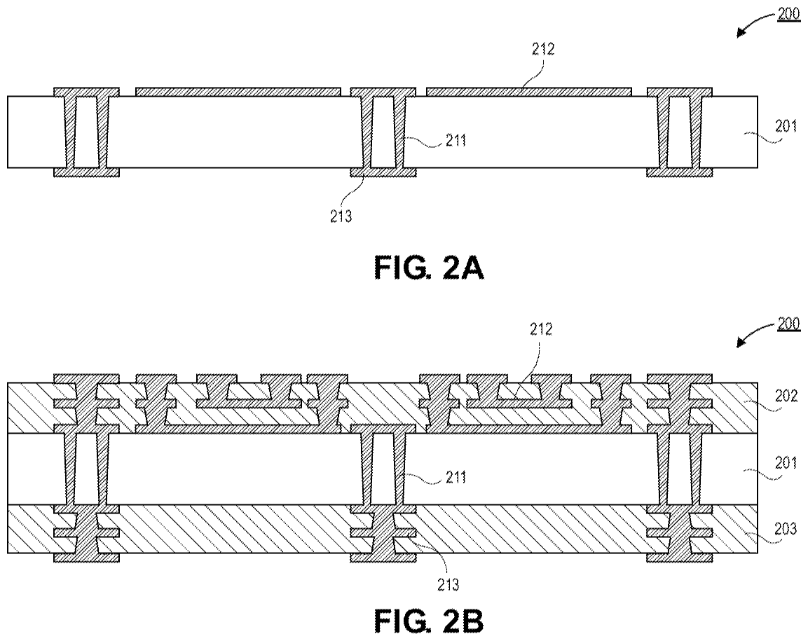

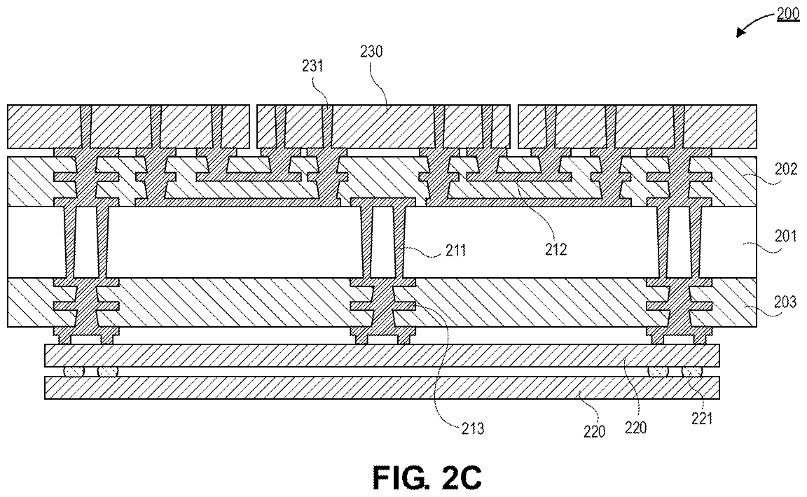

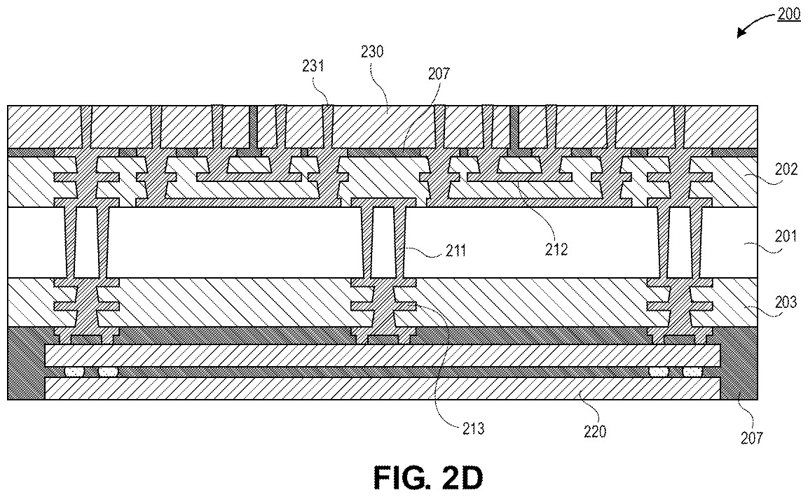

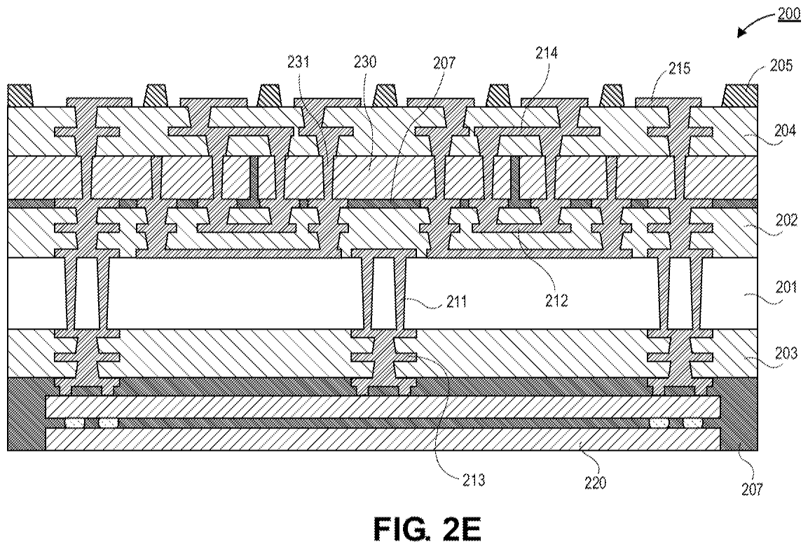

Referring now to FIGS. 2A-2E, a series of cross-sectional illustrations depicting a process for forming an electronic package 200 is shown, in accordance with an embodiment. In an embodiment, the electronic package 200 may be substantially similar to the electronic package 100 described in greater detail above. However, it is to be appreciated that similar processing operations with minor adjustments may be used in order to fabricate electronic packages similar to any of the electronic packages described in greater detail herein.

Referring now to FIG. 2A, a cross-sectional illustration of an electronic package 200 at a stage of manufacture is shown, in accordance with an embodiment. Particularly, a core 201 is shown in FIG. 2A. The core 201 may comprise glass. That is, core 201 may be a substrate that is substantially all a glass material. The core 201 may have one or more TGVs 211 formed through a thickness of the core 201. The TGVs 211 may be formed with a laser assisted patterning process, similar to the process described in greater detail above. As such, the TGVs 211 may have tapered sidewalls. In the illustrated embodiment, the TGVs 211 have a trapezoidal shaped cross-section. Though, in some embodiments, the TGVs 211 may have hourglass shaped cross-sections, or cross-sections with substantially vertical sidewalls. In an embodiment, the core 201 may have any suitable thickness. For example, a thickness of the core 201 may be between approximately 50 μm and approximately 1,000 μm. Though, thinner or thicker cores 201 may also be used in some embodiments.

In an embodiment, high density routing 212 may be provided over a top surface of the core 201. The high density routing 212 in FIG. 2A may be a first layer of high density routing. The high density routing 212 may have trace widths of approximately 2 μm or less and trace spacings of approximately 2 μm or less. In an embodiment, the fine line/spacing dimensions are enabled by the high planarity and stiffness of the core 201. The high density routing 212 may be electrically coupled to the TGVs 211 at some locations. Additionally, conductive routing 213 may be provided on the opposite side of the core 201 from the high density routing 212. The conductive routing 213 may have wider line/spacing dimensions. In a particular embodiment, the conductive routing 213 may comprise pads that are over the TGVs 211.

Referring now to FIG. 2B, a cross-sectional illustration of the electronic package 200 after first buildup layers 202 and second buildup layers 203 are formed over opposite surfaces of the core 201 is shown, in accordance with an embodiment. In an embodiment, the first buildup layers 202 may comprise the high density routing 212. That is, the high density routing 212 (e.g., pads, traces, vias, etc.) may be provided in one or more dielectric buildup film layers. The high density routing 212 may be fabricated with any patterning and deposition process that is capable of providing the small line/spacing requirements of the high density routing 212. As shown, the high density routing 212 may include traces that couple together laterally adjacent pads over the first buildup layers 202. This enables the high density routing 212 to couple together dies that will be added in a subsequent processing operation. In the illustrated embodiment, three routing layers are provided in the high density routing 212. Though, it is to be appreciated that any number of routing layers may be provided in the first buildup layers 202.

In an embodiment, second buildup layers 203 may be provided on the opposite side of the core 201 from the first buildup layers 202. Conductive routing 213 may be provided in the second buildup layers 203. In some embodiments, the dimensions and/or spacing of the conductive routing 213 in the second buildup layers 203 may be greater than the line/spacing dimensions in the high density routing 212. For example, the conductive routing 213 may be configured to provide power to subsequently added second dies, such as memory dies. In the illustrated embodiment, three routing layers are provided in the conductive routing 213. Though, it is to be appreciated that any number of routing layers may be provided in the second buildup layers 203.

Referring now to FIG. 2C, a cross-sectional illustration of the electronic package 200 after the attachment of first dies 230 and second dies 220 is shown, in accordance with an embodiment. In an embodiment, the first dies 230 may be compute dies, such as those described in greater detail above. In a particular embodiment, the first dies 230 may be referred to as die tiles. That is, the first dies 230 may be communicatively and electrically coupled together to function as single compute system. While three first dies 230 are shown, it is to be appreciated that any number of first dies 230 may be included in the electronic package 200. In an embodiment, the first dies 230 are electrically coupled together by the high density routing 212 in the first buildup layers 202. The first dies 230 may be electrically coupled to the high density routing 212 using any suitable FLI architecture. For example, the first dies 230 may be coupled to the high density routing 212 using hybrid bonding, solder, micro balls, or the like. In the illustrated embodiment, the first dies 230 may also include TSVs 231. The TSVs 231 allow for power and/or signals to pass through a thickness of the first dies 230 in order to enable 3D integration, as will be described in greater detail below.

In an embodiment, the second dies 220 may be attached to the second buildup layers 203 on the opposite side of the core 201 from the first dies 230. The second dies 220 may include memory dies in some instances. In the illustrated embodiment, a stack of two second dies 220 is shown. The second dies 220 may be coupled together by solder balls 221. In other embodiments, wire bonds may be used to couple the conductive routing 213 to the second dies 220. While two second dies 220 are shown, it is to be appreciated that any number of second dies 220 may be included in the stack, in order to provide a desired memory capacity to the electronic package 200.

Referring now to FIG. 2D, a cross-sectional illustration of the electronic package 200 after mold layers 207 are formed around the first dies 230 and the second dies 220 is shown, in accordance with an embodiment. The mold layers 207 may be any suitable molding material. For example, the mold layers 207 may include an organic dielectric material. The mold layers 207 may also provide an underfill between the dies 230/220 and the underlying buildup layers 202/203. In other embodiments, a dedicated underfill material (not shown) that is different than the mold layers 207 may be provided between the dies 230/220 and the underlying buildup layers 202/203. The mold layers 207 may be considered to embed the dies 230/220. That is, the mold layers 207 may cover the entire sidewall surfaces of the dies 230/220. However, the top surface of the first dies 230 and the bottom surface of the bottommost second die 220 may be exposed. In some embodiments, the second dies 220 may be fully embedded such that even the bottommost second die 220 has the bottom surface covered by the mold layer 207. The mold layers 207 may be applied using any molding or deposition process.

Referring now to FIG. 2E, a cross-sectional illustration of the electronic package 200 after third buildup layers 204 are formed is shown, in accordance with an embodiment. In an embodiment, the third buildup layers 204 may include conductive routing 214. The conductive routing 214 (e.g., pads, traces, vias, etc.) may electrically couple the TSVs 231 to SLI pads 215 in a solder resist layer 205. In this way, the electronic package 200 allows for truly 3D interconnect architectures. That is, high density routing 212 provides routing in a first plane (X-direction and Y-direction), and conductive routing 214 and 213 provides routing in a third dimension (Z-direction). In an embodiment, the conductive routing 214 may have line/space dimensions that are greater than the line/space dimension of the high density routing 212.

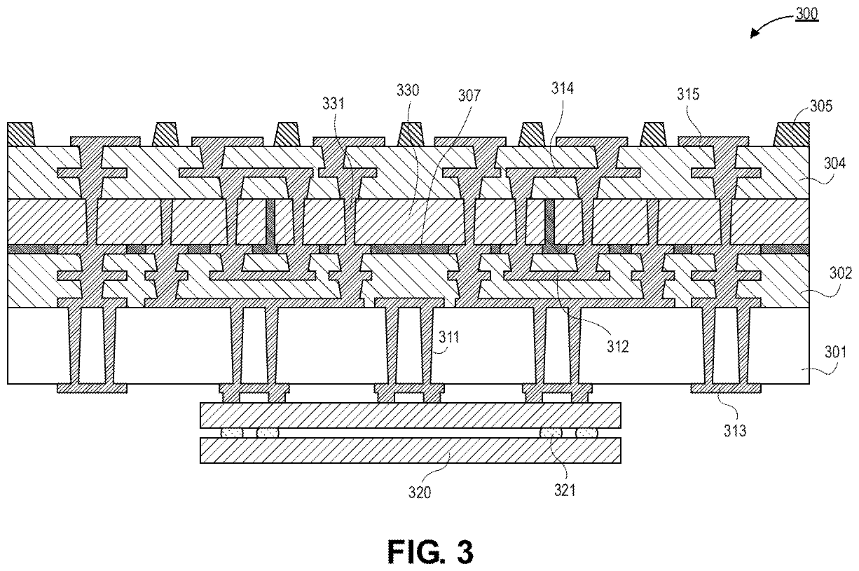

Referring now to FIG. 3, a cross-sectional illustration of an electronic package 300 is shown, in accordance with an additional embodiment. In an embodiment, the electronic package 300 comprises a core 301. The core 301 may comprise glass. In an embodiment, the core 301 has a thickness that is between approximately 50 μm and approximately 1,000 μm. The core 301 may have a glass formulation that is suitable for laser assisted patterning. In an embodiment, TGVs 311 are provided through the core 301. While shown with a trapezoidal cross-section, the TGVs 311 may also include hourglass shaped cross-sections, or the TGVs 311 may have substantially vertical sidewalls.

In an embodiment, pads 313 may be provided on a surface of the core 301. The pads 313 may be electrically coupled to one or more second dies 320. The second dies 320 may comprise memory dies in some instances. The second dies 320 may be coupled together by solder 321. In other embodiments, wire bonds or the like may be used to couple the second dies 320 to the pads 313. In the illustrated embodiment, the second dies 320 are provided without a mold layer. Though, in other embodiments, the second dies 320 may be embedded in a mold layer (not shown).

In an embodiment, first buildup layers 302 may be provided over the core 301 opposite from the second dies 320. The first buildup layers 302 may comprise high density routing 312 (e.g., pads, traces, vias, etc.). The high density routing 312 is enabled due to the high planarity and stiffness of the core 301. For example, the high density routing 312 may include trace widths of approximately 2 μm or less, and trace spacings of approximately 2 μm or less. In an embodiment, the high density routing 312 electrically couples together the two or more first dies 330. While three first dies 330 are shown, it is to be appreciated that any number of first dies 330 may be electrically coupled together using the high density routing 312. In an embodiment, the first dies 330 may be electrically coupled to the high density routing 312 using any suitable FLI architecture, such as hybrid bonding, solder, micro balls, or the like. In an embodiment, the first dies 330 may be embedded in a mold layer 307. That is, the mold layer may cover sidewalls of the first dies 330. In an embodiment, the first dies 330 may also comprise TSVs 331. The TSVs 331 provided electrical coupling through thicknesses of the first dies 330.

In an embodiment, the TSVs 331 may be electrically coupled to conductive routing (e.g., pads, traces, vias, etc.) 314 in second buildup layers 304 over the first dies 330. The conductive routing 314 may have line/space dimensions that are greater than those of the high density routing 312. In an embodiment, the conductive routing 314 electrically couples the TSVs 331 to the SLI pads 315 in the solder resist layer 305.

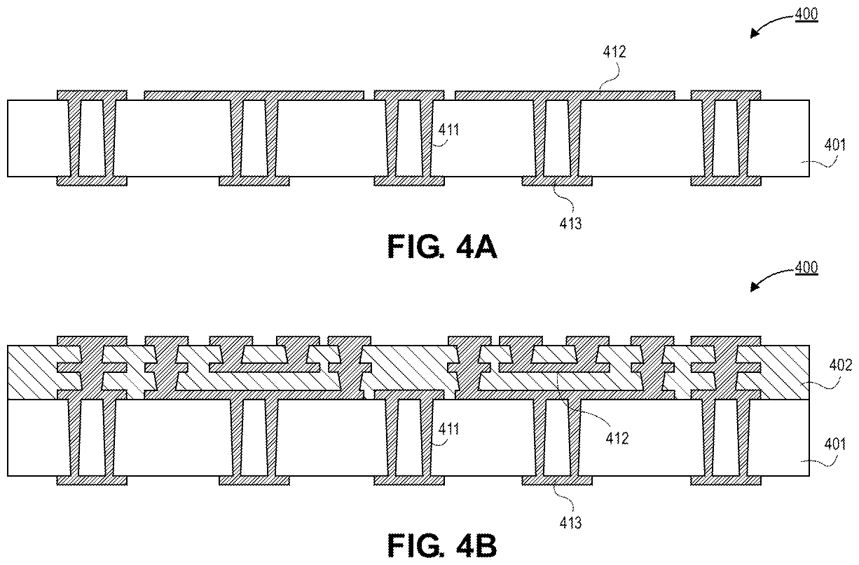

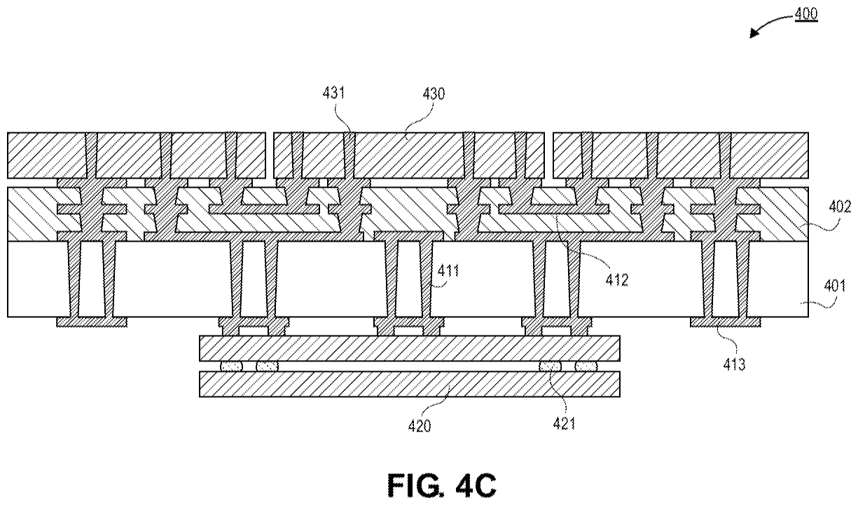

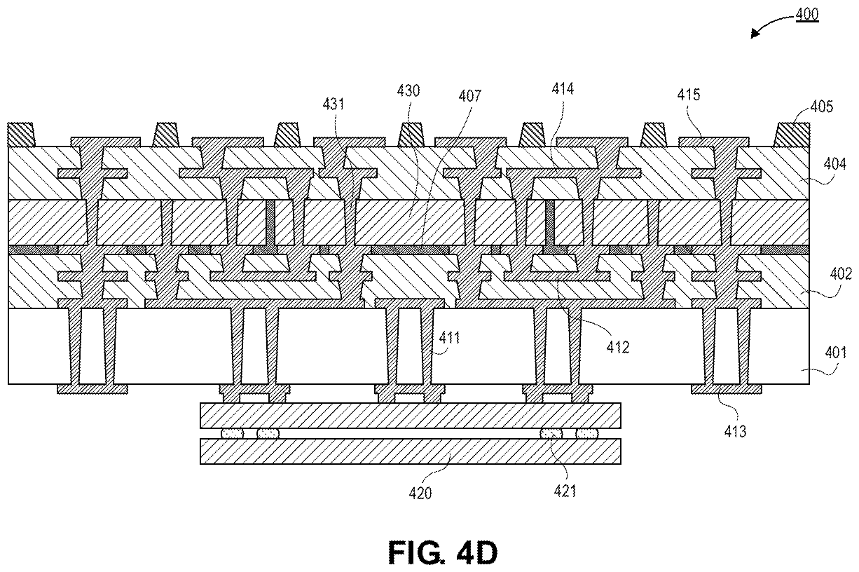

Referring now to FIGS. 4A-4D, a series of cross-sectional illustrations depicting a process for forming an electronic package 400 is shown, in accordance with an embodiment. The electronic package 400 may be substantially similar to the electronic package 300 described above. Though, it is to be appreciated that some changes to the process flow may be made in order to fabricate other electronic packages disclosed herein.

Referring now to FIG. 4A, a cross-sectional illustration of an electronic package 400 at a stage of manufacture is shown, in accordance with an embodiment. Particularly, a core 401 is shown in FIG. 4A. The core 401 may comprise glass. That is, core 401 may be a substrate that is substantially all a glass material. The core 401 may have one or more TGVs 411 formed through a thickness of the core 401. The TGVs 411 may be formed with a laser assisted patterning process, similar to the process described in greater detail above. As such, the TGVs 411 may have tapered sidewalls. In the illustrated embodiment, the TGVs 411 have a trapezoidal shaped cross-section. Though, in some embodiments, the TGVs 411 may have hourglass shaped cross-sections, or cross-sections with substantially vertical sidewalls. In an embodiment, the core 401 may have any suitable thickness. For example, a thickness of the core 401 may be between approximately 50 μm and approximately 1,000 μm. Though, thinner or thicker cores 401 may also be used in some embodiments.

In an embodiment, high density routing 412 may be provided over a top surface of the core 401. The high density routing 412 in FIG. 4A may be a first layer of high density routing. The high density routing 412 may have trace widths of approximately 2 μm or less and trace spacings of approximately 2 μm or less. In an embodiment, the fine line/spacing dimensions are enabled by the high planarity and stiffness of the core 401. The high density routing 412 may be electrically coupled to the TGVs 411 at some locations. Additionally, conductive routing 413 may be provided on the opposite side of the core 401 from the high density routing 412. The conductive routing 413 may have wider line/spacing dimensions. In a particular embodiment, the conductive routing 413 may comprise pads that are over the TGVs 411.

Referring now to FIG. 4B, a cross-sectional illustration of the electronic package 400 after first buildup layers 402 are formed over a surface of the core 401 is shown, in accordance with an embodiment. In an embodiment, the first buildup layers 402 may comprise the high density routing 412. That is, the high density routing 412 (e.g., pads, traces, vias, etc.) may be provided in one or more dielectric buildup film layers. The high density routing 412 may be fabricated with any patterning and deposition process that is capable of providing the small line/spacing requirements of the high density routing 412. As shown, the high density routing 412 may include traces that couple together laterally adjacent pads over the first buildup layers 402. This enables the high density routing 412 to couple together dies that will be added in a subsequent processing operation. In the illustrated embodiment, three routing layers are provided in the high density routing 412. Though, it is to be appreciated that any number of routing layers may be provided in the first buildup layers 402.

Referring now to FIG. 4C, a cross-sectional illustration of the electronic package 400 after the attachment of first dies 430 and second dies 420 is shown, in accordance with an embodiment. In an embodiment, the first dies 430 may be compute dies, such as those described in greater detail above. In a particular embodiment, the first dies 430 may be referred to as die tiles. That is, the first dies 430 may be communicatively and electrically coupled together to function as single compute system. While three first dies 430 are shown, it is to be appreciated that any number of first dies 430 may be included in the electronic package 400. In an embodiment, the first dies 430 are electrically coupled together by the high density routing 412 in the first buildup layers 402. The first dies 430 may be electrically coupled to the high density routing 412 using any suitable FLI architecture. For example, the first dies 430 may be coupled to the high density routing 412 using hybrid bonding, solder, micro balls, or the like. In the illustrated embodiment, the first dies 430 may also include TSVs 431. The TSVs 431 allow for power and/or signals to pass through a thickness of the first dies 430 in order to enable 3D integration.

In an embodiment, the second dies 420 may be attached to conductive routing 413 on the opposite side of the core 401 from the first dies 430. The second dies 420 may include memory dies in some instances. In the illustrated embodiment, a stack of two second dies 420 is shown. The second dies 420 may be coupled together by solder balls 421. In other embodiments, wire bonds may be used to couple the conductive routing 413 to the second dies 420. While two second dies 420 are shown, it is to be appreciated that any number of second dies 420 may be included in the stack, in order to provide a desired memory capacity to the electronic package 400.

Referring now to FIG. 4D, a cross-sectional illustration of the electronic package 400 after a mold layer 407 and second buildup layers 404 are formed over the first dies 430 is shown, in accordance with an embodiment. The mold layer 407 may be any suitable molding material. For example, the mold layer 407 may include an organic dielectric material. The mold layers 407 may also provide an underfill between the first dies 430 and the underlying first buildup layers 402. In other embodiments, a dedicated underfill material (not shown) that is different than the mold layer 407 may be provided between the first dies 430 and the underlying first buildup layers 402. The mold layer 407 may be considered to embed the first dies 430. That is, the mold layer 407 may cover the entire sidewall surfaces of the first dies 430. However, the top surface of the first dies 430 may be exposed. The mold layer 407 may be applied using any molding or deposition process.

In an embodiment, the second buildup layers 404 may include conductive routing 414. The conductive routing 414 (e.g., pads, traces, vias, etc.) may electrically couple the TSVs 431 to SLI pads 415 in a solder resist layer 405. In this way, the electronic package 400 allows for truly 3D interconnect architectures. In an embodiment, the conductive routing 414 may have line/space dimensions that are greater than the line/space dimension of the high density routing 412.

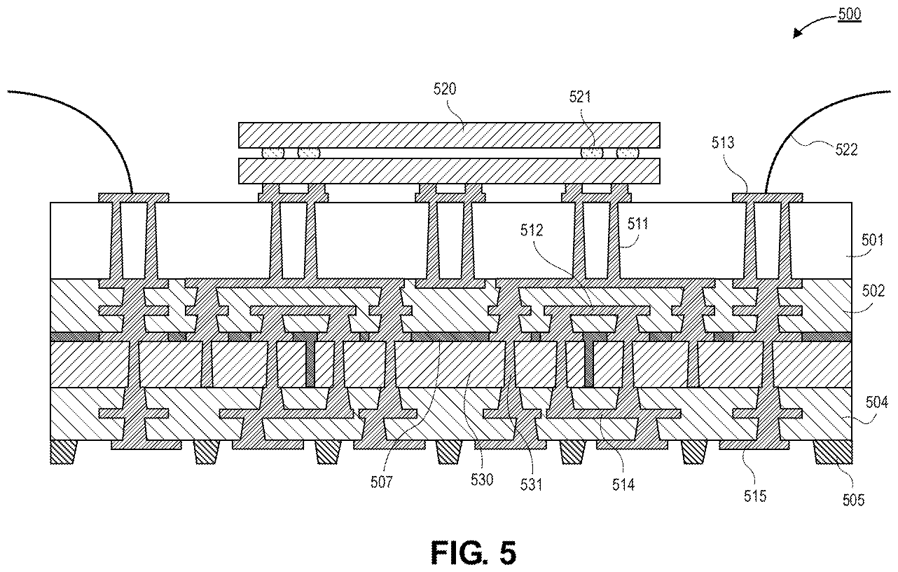

Referring now to FIG. 5, a cross-sectional illustration of an electronic package 500 is shown, in accordance with yet another embodiment. In an embodiment, the electronic package 500 may comprise a core 501. The core 501 may comprise glass. In an embodiment, TGVs 511 may pass through a thickness of the core 501. The TGVs 511 may have any shaped cross-section (e.g., trapezoidal, hourglass, rectangular), depending on the methods of forming the TGVs 511. The core 501 may have a thickness between approximately 50 μm and approximately 1,000 μm. Though, thinner or thicker cores 501 may also be used in some embodiments.

In an embodiment, first buildup layers 502 may be provided over a surface of the core 501. The first buildup layers 502 may include high density routing (e.g., pads, traces, vias, etc.) 512. The high density routing (e.g., line/space dimensions of 2 μm/2 μm or less) 512 is enabled due to the high planarity and stiffness of the core 501. The high density routing 512 may be electrically coupled to two or more first dies 530. The first dies 530 may be compute dies, such as those described above. In an embodiment, the high density routing 512 electrically couples the first dies 530 together so that they may function as a single compute die. The first dies 530 may be embedded in a mold layer 507. Additionally, the first dies 530 may comprise TSVs 531. In an embodiment, the TSVs 531 are electrically coupled to conductive routing (e.g., pads, traces, vias, etc.) 514 in the second buildup layers 504. The conductive routing 514 may electrically couple the TSVs 531 to SLI pads 515 in a solder resist layer 505.

In an embodiment, pads 513 may be provided on an opposite side of the core 501 from the first dies 530. The pads 513 may be coupled to one or more second dies 520. The second dies 520 may be memory dies in some embodiments. The second dies 520 may be coupled together by solder 521 or any other suitable interconnect architecture. In some embodiments, the pads 513 may also be coupled to wire bonds 522. The wire bonds 522 may be electrically coupled to other electronic packages (not shown), in order to provide even greater system integration.

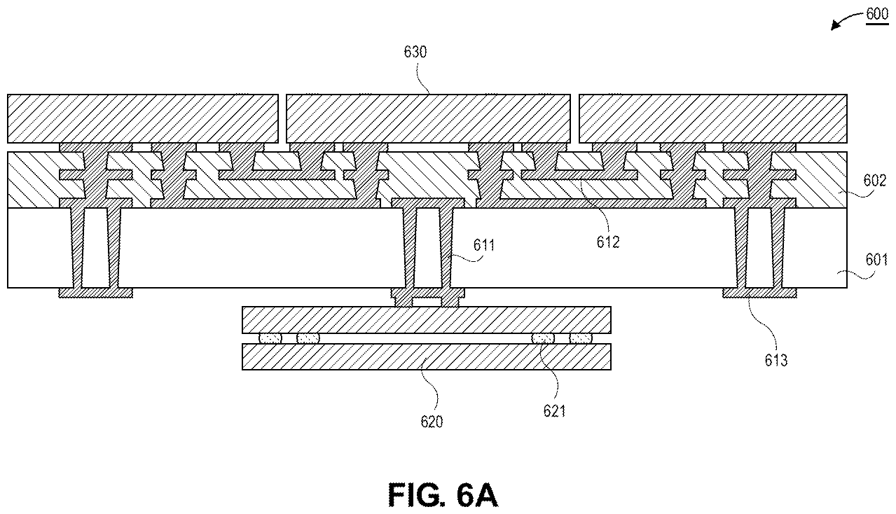

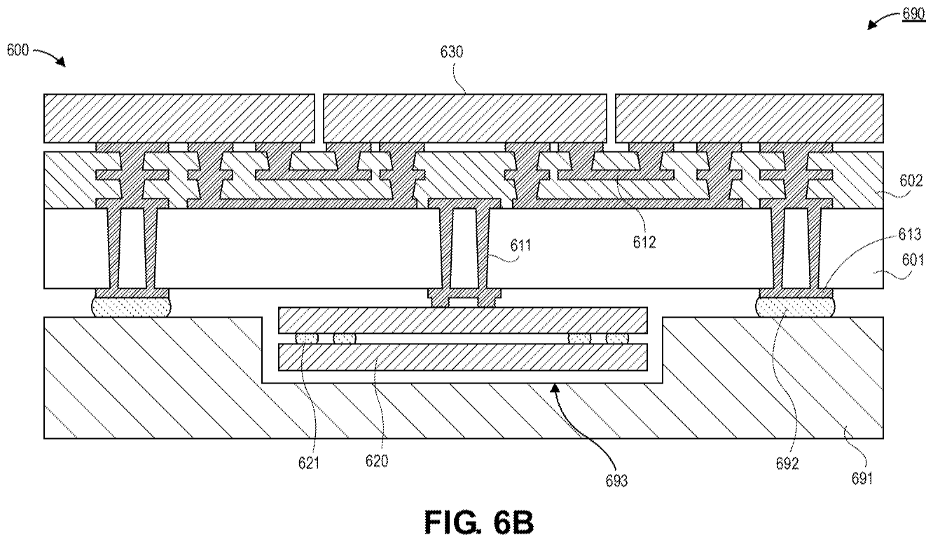

Referring now to FIG. 6A, a cross-sectional illustration of an electronic package 600 is shown, in accordance with yet another embodiment. In an embodiment, the electronic package 600 comprises a core 601. The core 601 may comprise glass. TGVs 611 may be provided through a thickness of the core 601. The TGVs 611 may have trapezoidal, hourglass, or rectangular shaped cross-sections. The core 601 may have a thickness between approximately 50 μm and approximately 1,000 μm. Though thinner or thicker cores 601 may be used in other embodiments.

In an embodiment, buildup layers 602 may be provided over the core 601. The buildup layers 602 may comprise high density routing (e.g., pads, traces, vias, etc.) 612. The high density routing 612 may include traces with line/space dimensions of approximately 2 μm/2 μm or smaller. The high density routing 612 may be enabled by the high planarity and stiffness of the core 601. The high density routing 612 may electrically couple first dies 630 together. For example, the first dies 630 may comprise compute dies, such as those described in greater detail above.

In an embodiment, second dies 620 may be provided over a surface of the core 601 opposite from the first dies 630. The second dies 620 may include memory dies. The second dies 620 may be coupled together by solder 621, wire bonds, or the like. The second dies 620 may be coupled to TGVs 611 through pads 613 formed on the backside of the core 601.

Referring now to FIG. 6B, a cross-sectional illustration of an electronic system 690 is shown, in accordance with an embodiment. In an embodiment, the electronic system 690 may comprise an electronic package 600 that is substantially similar to the electronic package 600 described above with respect to FIG. 6A. For example, the electronic package 600 comprises a core 601 with TGVs 611. High density routing 612 is provided in buildup layers 602 in order to couple together first dies 630. Second dies 620 are provided on the opposite side of the core 601 and are coupled to pads 613.

Additionally, the electronic system 690 comprises a board 691. The board 691 may be a printed circuit board (PCB) or the like. In an embodiment, interconnects 692, such as solder balls or the like electrically couple pads 613 to the board 691. In an embodiment, a cavity 693 may be provided into the top surface of the board 691. The cavity 693 is sized to receive the second dies 620 of the electronic package 600. As such, the overall height of the electronic system 690 can be reduced.

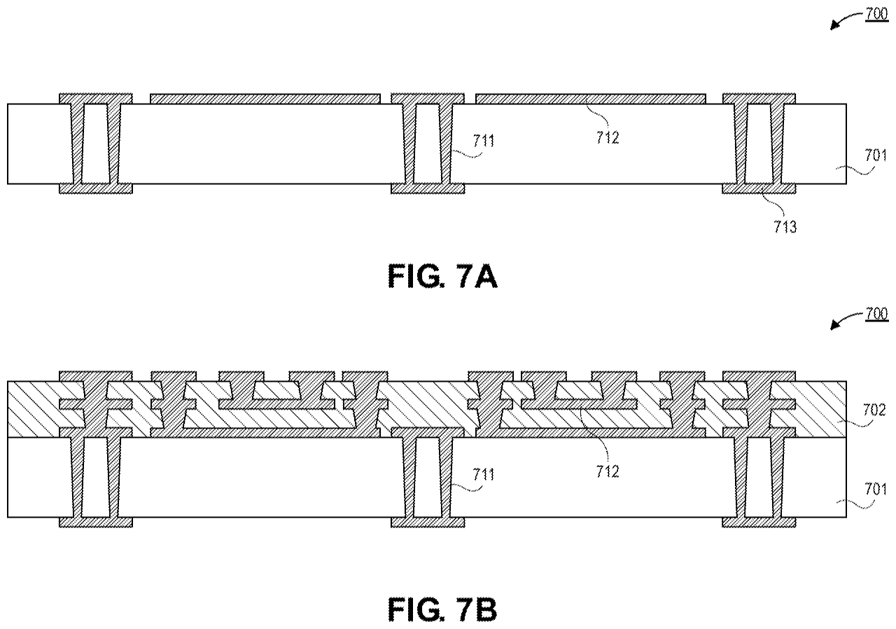

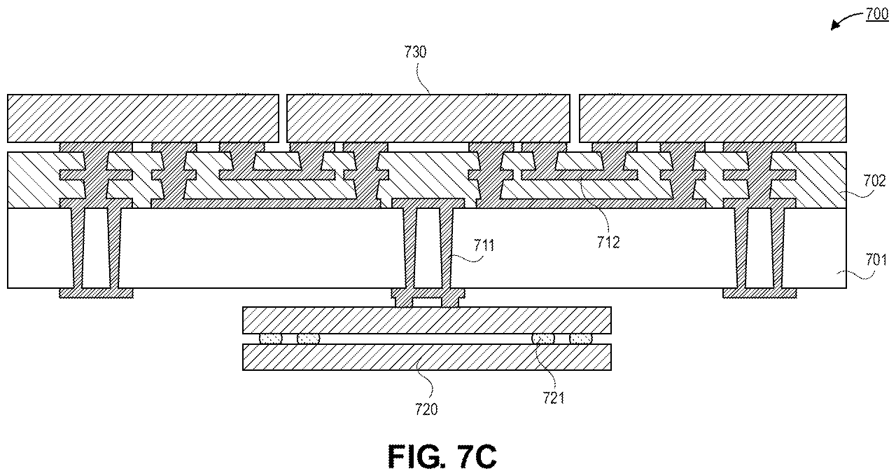

Referring now to FIGS. 7A-7C, a series of cross-sectional illustrations depicting a process for forming an electronic package 700 is shown, in accordance with an embodiment. In an embodiment, the electronic package 700 may be substantially similar to the electronic package 600 described above with respect to FIG. 6A. Though, it is to be appreciated that modifications to the process may be used to form electronic packages similar to any of the embodiments disclosed herein.

Referring now to FIG. 7A, a cross-sectional illustration of an electronic package 700 at a stage of manufacture is shown, in accordance with an embodiment. Particularly, a core 701 is shown in FIG. 7A. The core 701 may comprise glass. That is, core 701 may be a substrate that is substantially all a glass material. The core 701 may have one or more TGVs 711 formed through a thickness of the core 701. The TGVs 711 may be formed with a laser assisted patterning process, similar to the process described in greater detail above. As such, the TGVs 711 may have tapered sidewalls. In the illustrated embodiment, the TGVs 711 have a trapezoidal shaped cross-section. Though, in some embodiments, the TGVs 711 may have hourglass shaped cross-sections, or cross-sections with substantially vertical sidewalls. In an embodiment, the core 701 may have any suitable thickness. For example, a thickness of the core 701 may be between approximately 50 μm and approximately 1,000 μm. Though, thinner or thicker cores 701 may also be used in some embodiments.

In an embodiment, high density routing 712 may be provided over a top surface of the core 701. The high density routing 712 in FIG. 7A may be a first layer of high density routing. The high density routing 712 may have trace widths of approximately 2 μm or less and trace spacings of approximately 2 μm or less. In an embodiment, the fine line/spacing dimensions are enabled by the high planarity and stiffness of the core 701. The high density routing 712 may be electrically coupled to the TGVs 711 at some locations. Additionally, conductive routing 713 may be provided on the opposite side of the core 701 from the high density routing 712. In a particular embodiment, the conductive routing 713 may comprise pads that are over the TGVs 711.

Referring now to FIG. 7B, a cross-sectional illustration of the electronic package 700 after buildup layers 702 are formed over a surface of the core 701 is shown, in accordance with an embodiment. In an embodiment, the buildup layers 702 may comprise the high density routing 712. That is, the high density routing 712 (e.g., pads, traces, vias, etc.) may be provided in one or more dielectric buildup film layers. The high density routing 712 may be fabricated with any patterning and deposition process that is capable of providing the small line/spacing requirements of the high density routing 712. In the illustrated embodiment, three routing layers are provided in the high density routing 712. Though, it is to be appreciated that any number of routing layers may be provided in the buildup layers 702.

Referring now to FIG. 7C, a cross-sectional illustration of the electronic package 700 after the attachment of first dies 730 and second dies 720 is shown, in accordance with an embodiment. In an embodiment, the first dies 730 may be compute dies, such as those described in greater detail above. In a particular embodiment, the first dies 730 may be referred to as die tiles. That is, the first dies 730 may be communicatively and electrically coupled together to function as single compute system. While three first dies 730 are shown, it is to be appreciated that any number of first dies 730 may be included in the electronic package 700. In an embodiment, the first dies 730 are electrically coupled together by the high density routing 712 in the buildup layers 702. The first dies 730 may be electrically coupled to the high density routing 712 using any suitable FLI architecture. For example, the first dies 730 may be coupled to the high density routing 712 using hybrid bonding, solder, micro balls, or the like.

In an embodiment, the second dies 720 may be attached to conductive routing 713 on the opposite side of the core 701 from the first dies 730. The second dies 720 may include memory dies in some instances. In the illustrated embodiment, a stack of two second dies 720 is shown. The second dies 720 may be coupled together by solder balls 721. In other embodiments, wire bonds may be used to couple the conductive routing 713 to the second dies 720. While two second dies 720 are shown, it is to be appreciated that any number of second dies 720 may be included in the stack, in order to provide a desired memory capacity to the electronic package 700.

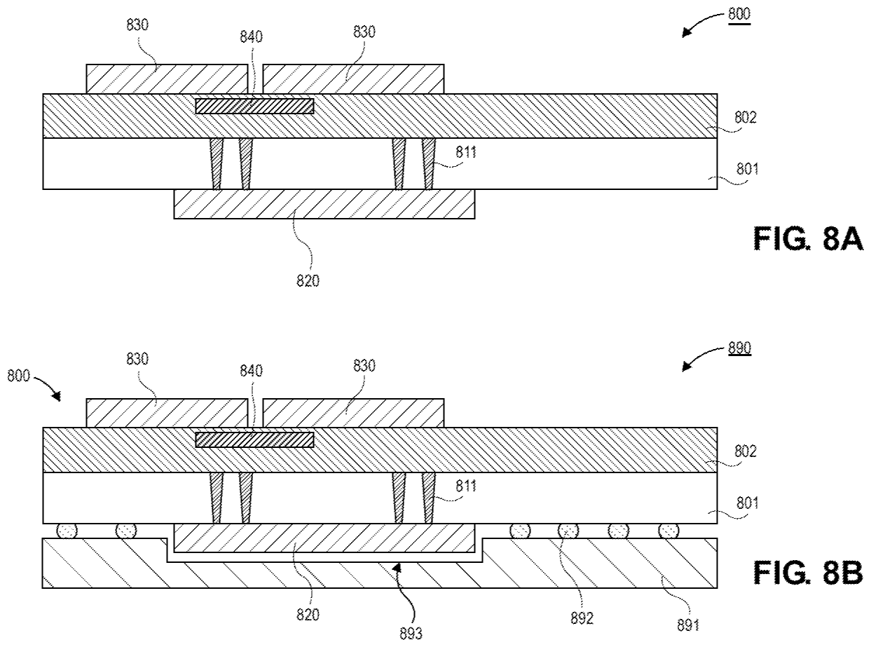

Referring now to FIG. 8A, a cross-sectional illustration of an electronic package 800 is shown, in accordance with yet another embodiment. In an embodiment, the electronic package 800 may comprise a core 801. The core 801 may comprise glass. The core 801 may have a thickness between approximately 50 μm and approximately 1,000 μm. Though, thinner or thicker cores 801 may also be used in some embodiments. In an embodiment, TGVs 811 may pass through a thickness of the core 801. The TGVs 801 may have cross-sections that are trapezoidal shaped, hourglass shaped, or rectangular.

In an embodiment, buildup layers 802 may be provided above the core 801. In an embodiment, a bridge 840 may be at least partially embedded in the buildup layers 802. The bridge 840 may comprise silicon or another dimensionally stable substrate. The bridge 840 may comprise high density routing in order to electrically couple together two or more first dies 830. While a single bridge 840 is shown, it is to be appreciated that multiple bridges 840 may be used in some embodiments. The high density routing in the bridge 840 may have line/space dimensions of 2 μm/2 μm or smaller. In an embodiment the first dies 830 may be coupled to the bridge 840 through any FLI architecture, such as hybrid bonding, solder, micro balls, or the like.

In an embodiment, a second die 820 may be provided over a surface of the core 801 opposite from the first dies 830. In an embodiment, the second die 820 may comprise a memory die. The first dies 830 may be electrically coupled to the second die 820 through one or more of the TGVs 811. The second die 820 may be coupled to the core 801 through any interconnect architecture, such as solder, micro balls, hybrid bonding, or the like.

Referring now to FIG. 8B, a cross-sectional illustration of an electronic system 890 is shown, in accordance with an embodiment. In an embodiment, the electronic system 890 may include an electronic package 800 that is substantially similar to the electronic package 800 described above with respect to FIG. 8A. For example, the electronic package 800 may comprise a core 801 with buildup layers 802 over the core 801. A bridge 840 may electrically couple the first dies 830 together. In an embodiment, a second die 820 is provided below the core 801.

In an embodiment, the electronic system 890 further comprises a board 891, such as a PCB. The board 891 may be coupled to the core 801 through solder balls 892, or any other suitable interconnect architecture. In an embodiment, a cavity 893 may be provided in the board 891. The cavity 893 is sized to accommodate the thickness of the second die 820. As such, the overall thickness of the electronic system 890 can be reduced.

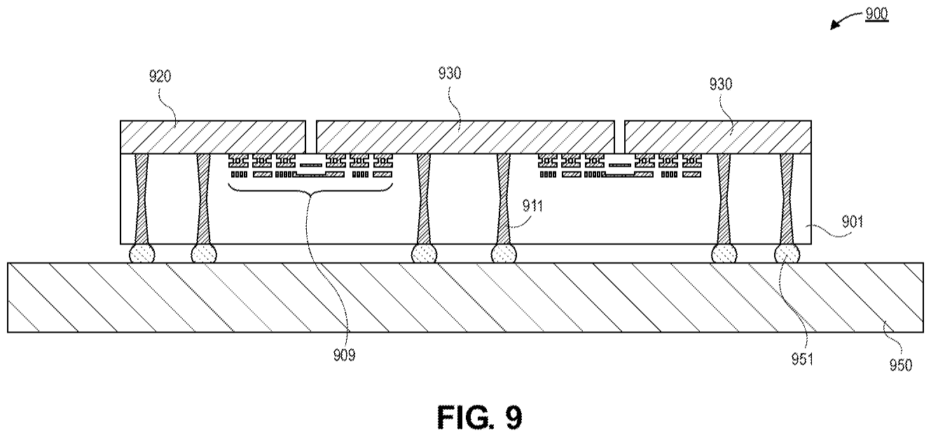

Referring now to FIG. 9, a cross-sectional illustration of an electronic package 900 is shown, in accordance with an embodiment. In an embodiment, the electronic package 900 may comprise a core 901. The core 901 may comprise glass. The core 901 may have a thickness between approximately 50 μm and approximately 1,000 μm. In an embodiment, TGVs 911 are provided through a thickness of the core 901. As shown, the TGVs 911 have an hourglass shaped cross-section. Though, it is to be appreciated that the TGVs 911 may have other cross-sectional shapes, as described above.

In an embodiment, high density routing 909 may be fabricated into the core 901. The high density routing 909 may have line/space dimensions of approximately 2 μm/2 μm or less. In an embodiment, the high density routing 909 may electrically couple together dies 930 and 920. For example, dies 930 may be compute dies, and die 920 may be a memory die. That is, the compute dies 930 and the memory die 920 may both be on the same side of the core 901 in some embodiments. The dies 920 and 930 may be coupled to the high density routing 909 by any FLI architecture, such as hybrid bonding, solder, micro balls, or the like.

In an embodiment, the core 901 may be electrically coupled to an underlying substrate 950 by interconnects 951. The underlying substrate 950 may be a conventional (organic) package substrate. In other embodiments, the underlying substrate 950 may be a board, such as a PCB.

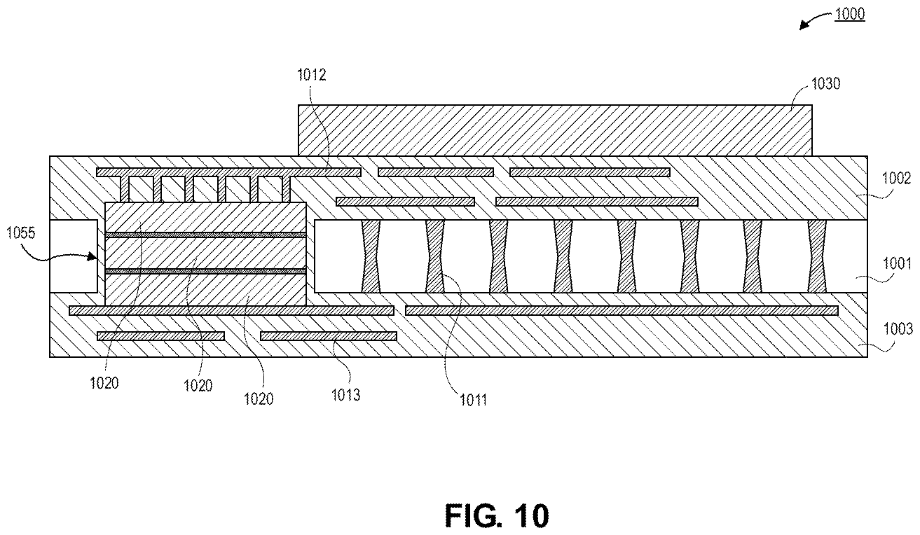

Referring now to FIG. 10, a cross-sectional illustration of an electronic package 1000 is shown, in accordance with an additional embodiment. In an embodiment, the electronic package 1000 comprises a core 1001. The core may comprise glass and include TGVs 1011. The TGVs 1011 may have any suitable cross-section. For example, hourglass shaped cross sections are shown for the TGVs 1011 in FIG. 10. In an embodiment, first buildup layers 1002 may be provided above the core 1001, and second buildup layers 1003 may be provided below the core 1001. Conductive routing (e.g., pads, traces, vias, etc.) 1012 and conductive routing (e.g., pads, traces, vias, etc.) 1013 may be provided in the buildup layers 1002 and 1003. In some embodiments, the conductive routing 1012 or 1013 may include high density conductive routing with line/space dimensions of approximately 2 μm/2 μm or less.

In an embodiment, a first die 1030 may be provided over the buildup layers 1002. The first die 1030 may comprise a compute die. While a single first die 1030 is shown, it is to be appreciated that any number of first dies 1030 may be used. For example, high density routing 1012 may couple together multiple first dies 1030 in some embodiments. In an embodiment, one or more second dies 1020 (e.g., memory dies) may be provided in a cavity 1055 in the core 1001. The second dies 1020 may comprise memory dies in some instances. The second dies 1020 may be electrically coupled to the first die 1030 through conductive routing 1012.

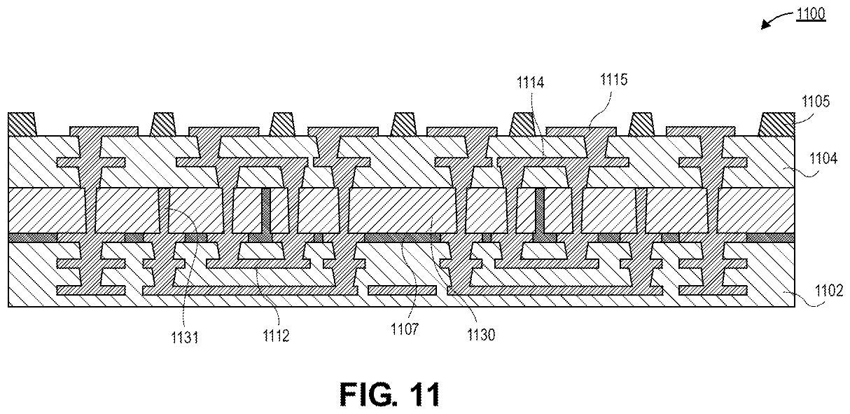

Referring now to FIG. 11, a cross-sectional illustration of an electronic package 1100 is shown, in accordance with an additional embodiment. In an embodiment, the electronic package 1100 includes first buildup layers 1102. In an embodiment, high density routing 1112 is provided in the first buildup layers 1102. It is to be appreciated that high density routing 1112 is typically not able to be formed in buildup layers. However, as will be described in greater detail below, the electronic package 1100 is formed on a carrier substrate, such as a glass substrate. The glass substrate is subsequently removed in order to leave the first buildup layers 1102 exposed. The high density routing 1112 may have line/space dimensions of approximately 2 μm/2 μm or less.

In an embodiment, two or more dies 1130 are provided over the first buildup layers 1102. The dies 1130 may be compute dies, such as those described in greater detail above. In an embodiment, the dies 1130 may be electrically coupled to each other by the high density routing 1112 in the first buildup layers 1102. In an embodiment, a mold layer 1107 may be provided around the dies 1130. The dies 1130 may also include TSVs 1131. In an embodiment, second buildup layers 1104 may be provided over the dies 1130. Conductive routing 1114 may be provided in the second buildup layers 1104. The conductive routing 1114 may electrically couple the TSVs 1131 to SLI pads 1115 in a solder resist layer 1105.

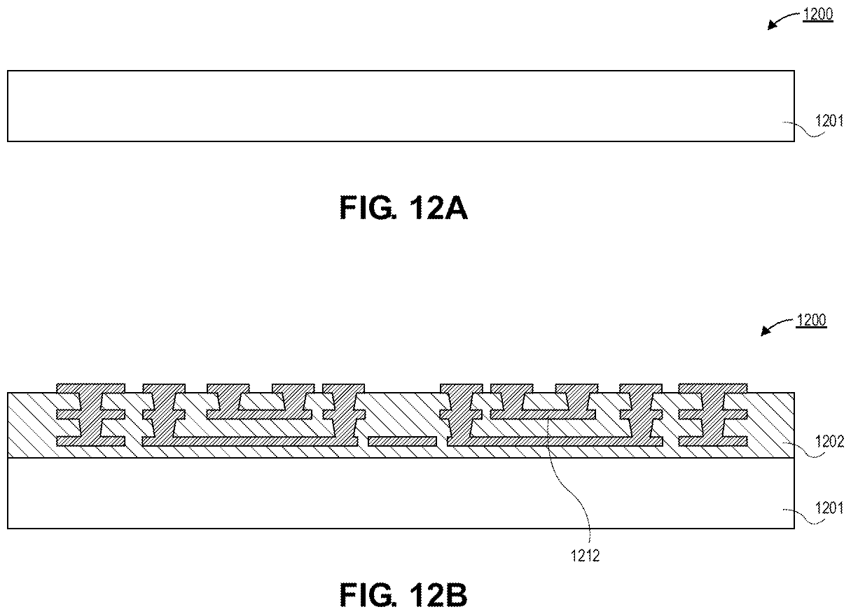

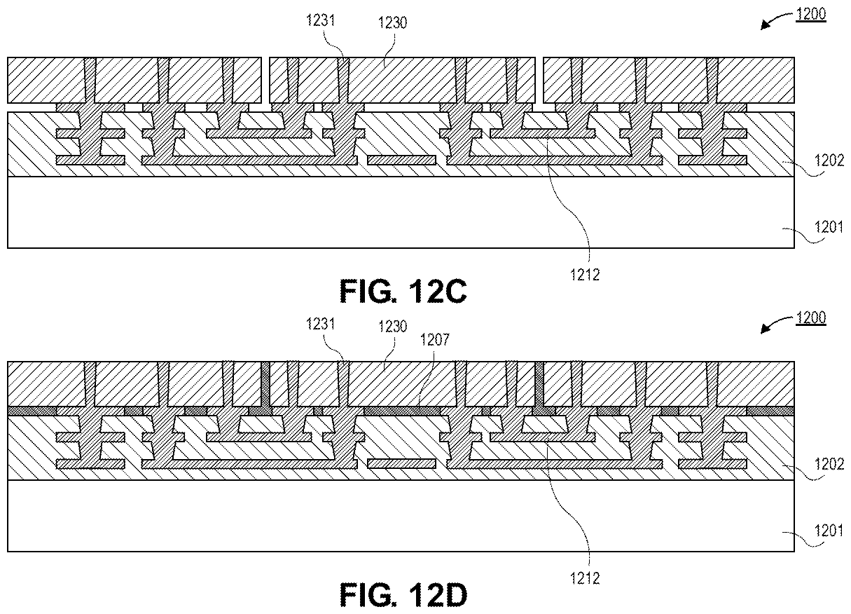

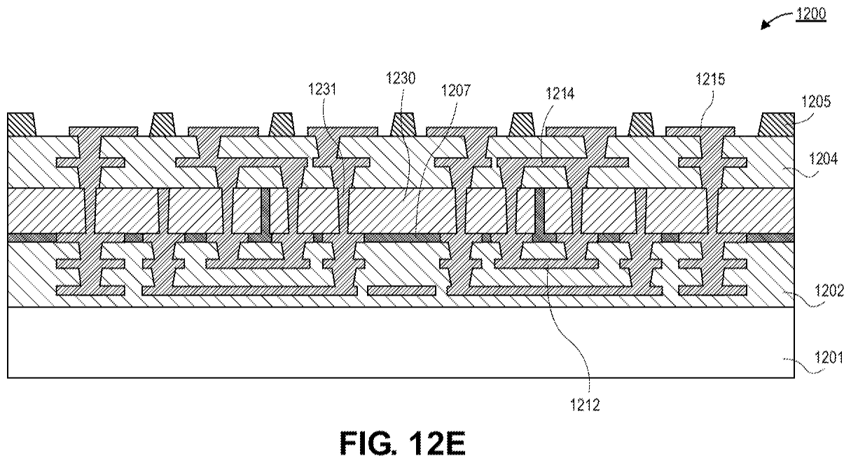

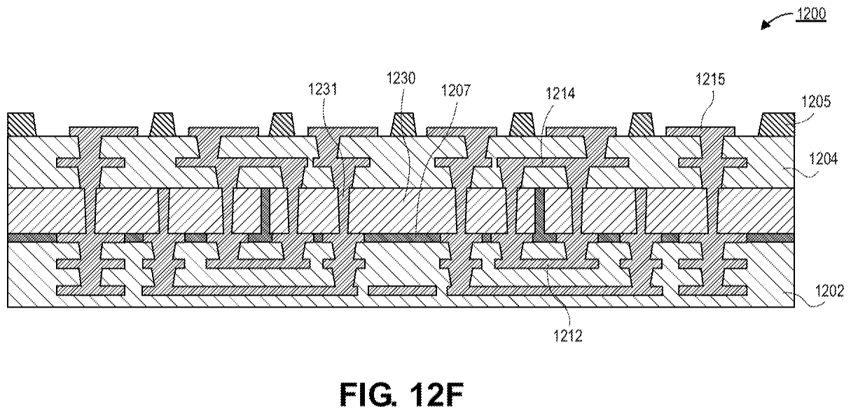

Referring now to FIGS. 12A-12F, a series of cross-sectional illustrations depicting a process for forming an electronic package 1200 is shown, in accordance with an embodiment. In an embodiment, the electronic package 1200 may be substantially similar to the electronic package 1100 described above with respect to FIG. 11.

Referring now to FIG. 12A, a cross-sectional illustration of an electronic package 1200 at a stage of manufacture is shown, in accordance with an embodiment. In an embodiment, a carrier substrate 1201 is shown. In an embodiment, the carrier substrate 1201 is a dimensionally stable substrate that has a highly planar (flat) surface. For example, the carrier substrate 1201 may comprise a glass substrate.

Referring now to FIG. 12B, a cross-sectional illustration of the electronic package 1200 after first buildup layers 1202 are formed over the carrier substrate 1201 is shown, in accordance with an embodiment. In an embodiment, the first buildup layers 1202 may comprise high density routing 1212. The high density routing 1212 may include line/space dimensions of approximately 2 μm/2 μm or less. The fine line/space dimensions are possible because of the dimensional stability and flatness of the carrier substrate 1201.

Referring now to FIG. 12C, a cross-sectional illustration of the electronic package 1200 after dies 1230 are attached to the first buildup layers 1202 is shown, in accordance with an embodiment. In an embodiment, the dies 1230 may be compute dies. Additionally, the dies 1230 may be electrically coupled to each other by the high density routing 1212 in the first buildup layers 1202. In an embodiment, the dies 1230 may be coupled to the high density routing 1212 by any FLI architecture. For example, hybrid bonding, solder, micro balls, or the like may be used to couple the dies 1230 to the high density routing 1212. In an embodiment, the dies 1230 may include TSVs 1231.

Referring now to FIG. 12D, a cross-sectional illustration of the electronic package 1200 after a mold layer 1207 is provided around the dies 1230 is shown, in accordance with an embodiment. The mold layer 1207 may embed the dies 1230. That is, the mold layer 1207 may cover the entire sidewalls of the dies 1230.

Referring now to FIG. 12E, a cross-sectional illustration of the electronic package 1200 after second buildup layers 1204 are provided over the dies 1230 is shown, in accordance with an embodiment. The second buildup layers 1204 may include conductive routing 1214 that couples the TSVs 1231 to SLI pads 1215 in the solder resist layer 1205.

Referring now to FIG. 12F, a cross-sectional illustration of the electronic package 1200 after the carrier substrate 1201 is removed is shown, in accordance with an embodiment. In an embodiment, the carrier substrate 1201 may be removed with a delamination process. The removal of the carrier substrate 1201 may result in a bottom surface of the first buildup layers 1202 being exposed. As such, high density routing 1212 may be provided without the presence of a glass core or other type of core material.

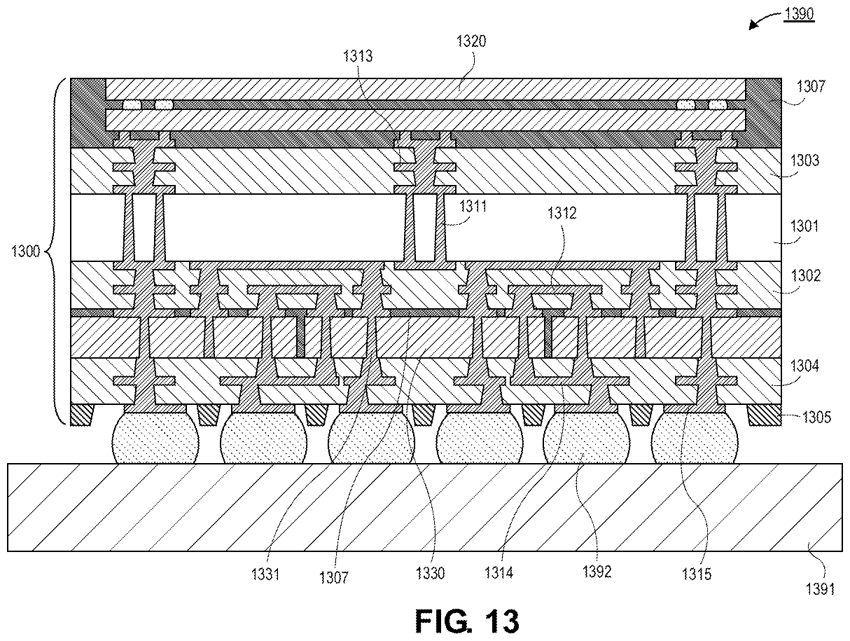

Referring now to FIG. 13, a cross-sectional illustration of an electronic system 1390 is shown, in accordance with an embodiment. In an embodiment, the electronic system 1390 may include an electronic package 1300 that is coupled to a board 1391, such as a PCB. In an embodiment, the electronic package 1300 is coupled to the board 1391 with interconnects 1392, such as solder interconnects or the like. The interconnects 1392 may be provided on SLI pads 1315 in the solder resist layer 1305.

In an embodiment, the electronic package 1300 may comprise a core 1301, such as a glass core. In an embodiment, first buildup layers 1302 are provided under the core 1301. High density routing 1312 is provided in the first buildup layers 1302. The high density routing 1312 electrically couples together first dies 1330 in mold layer 1307. TSVs 1331 in the first dies 1330 are coupled to the SLI pads 1315 with conductive routing 1314 in third buildup layers 1304.

In an embodiment, second buildup layers 1303 may be provided over the core 1301. Conductive routing 1313 may be provided in the second buildup layers 1303. The conductive routing 1313 may couple the TGVs 1311 to second dies 1320 over the second buildup layers 1303. The second dies 1320 may be memory dies. A mold layer 1307 may be provided around the second dies 1320.

In the illustrated embodiment, the electronic system 1390 includes an electronic package 1300 that is substantially similar to the electronic package 100 shown in FIG. 1. However, it is to be appreciated that any of the electronic packages described herein may be integrated with a board 1391 in order to form an electronic system 1390.

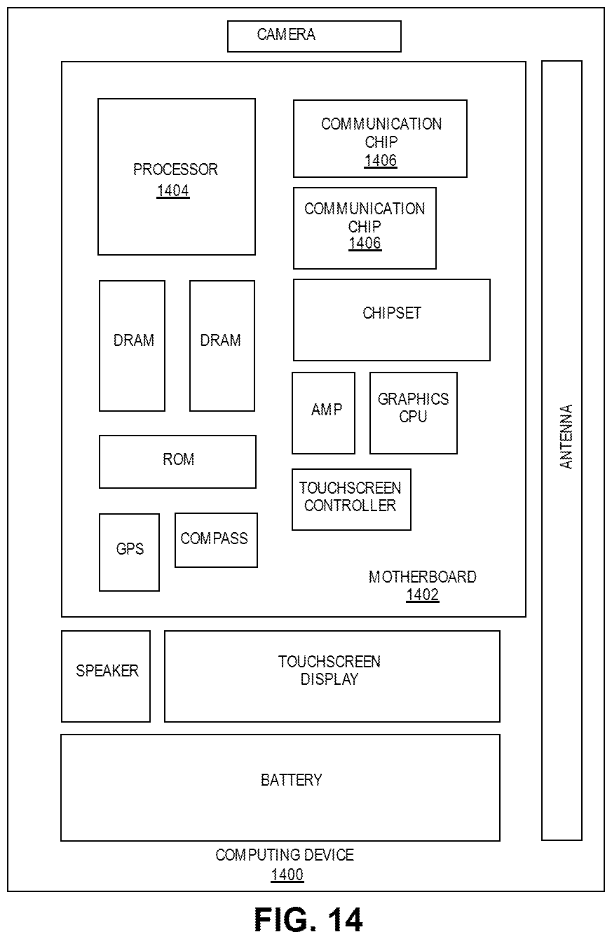

FIG. 14 illustrates a computing device 1400 in accordance with one implementation of the invention. The computing device 1400 houses a board 1402. The board 1402 may include a number of components, including but not limited to a processor 1404 and at least one communication chip 1406. The processor 1404 is physically and electrically coupled to the board 1402. In some implementations the at least one communication chip 1406 is also physically and electrically coupled to the board 1402. In further implementations, the communication chip 1406 is part of the processor 1404.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1406 enables wireless communications for the transfer of data to and from the computing device 1400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1406 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1400 may include a plurality of communication chips 1406. For instance, a first communication chip 1406 may be dedicated to shorter range wireless communications such as Wi-Fi and Bluetooth and a second communication chip 1406 may be dedicated to longer range wireless communications such as GPS, EDGE, GPRS, CDMA, WiMAX, LTE, Ev-DO, and others.

The processor 1404 of the computing device 1400 includes an integrated circuit die packaged within the processor 1404. In some implementations of the invention, the integrated circuit die of the processor may be part of an electronic system that includes high density routing in buildup layers over a glass core, in accordance with embodiments described herein. The term “processor” may refer to any device or portion of a device that processes electronic data from registers and/or memory to transform that electronic data into other electronic data that may be stored in registers and/or memory.

The communication chip 1406 also includes an integrated circuit die packaged within the communication chip 1406. In accordance with another implementation of the invention, the integrated circuit die of the communication chip may be part of an electronic system that includes high density routing in buildup layers over a glass core, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a substrate, wherein the substrate comprises glass; buildup layers over the first substrate; a first die over the buildup layers; a second die over the buildup layers and adjacent to the first die, and wherein conductive routing in the buildup layers electrically couples the first die to the second die.

Example 2: the electronic package of Example 1, wherein the conductive routing includes traces with a line thickness of approximately 2 μm or less and a line spacing of approximately 2 μm or less.

Example 3: the electronic package of Example 1 or Example 2, wherein the first die and the second die comprise through silicon vias (TSVs).

Example 4: the electronic package of Example 3, further comprising: second buildup layers over the first die and the second die, wherein the TSVs are coupled to pads on a surface of the second buildup layers.

Example 5: the electronic package of Examples 1-4, further comprising: a third die on an opposite surface of the substrate from the first die and the second die.

Example 6: the electronic package of Example 5, wherein the third die is a memory die.

Example 7: the electronic package of Example 5 or Example 6, wherein through glass vias (TGVs) are provided through the substrate.

Example 8: the electronic package of Examples 1-7, wherein a mold layer is provided around the first die and the second die.

Example 9: the electronic package of Examples 1-8, wherein the first die and the second die are compute dies.

Example 10: the electronic package of Examples 1-9, wherein the substrate has a thickness that is between approximately 50 μm and approximately 1,000 μm.

Example 11: a method of forming an electronic package, comprising: forming through glass vias (TGVs) through a core comprising glass; forming first buildup layers over the core, wherein the first buildup layers comprise routing with line/space dimensions of approximately 2 μm/2 μm or less; forming second buildup layers over the core opposite from the first buildup layers; attaching a first die and a second die to the routing in the first buildup layers; forming a mold layer around the first die and the second die; and forming third buildup layers over the mold layer.

Example 12: the method of Example 11, wherein the first die and the second die are attached to the routing in the first buildup layer with hybrid bonding.

Example 13: the method of Example 11 or Example 12, wherein the first die and the second die are attached to the routing in the first buildup layer with solder.

Example 14: the method of Examples 11-13, wherein the first die and the second die are attached to the routing in the first buildup layer with micro balls.

Example 15: the method of Examples 11-14, further comprising: attaching a third die to routing in the second buildup layers.

Example 16: the method of Example 15, wherein the third die is a memory die.

Example 17: the method of Example 15 or Example 16, wherein the third die is embedded in a second mold layer.

Example 18: the method of Examples 11-17, wherein the first die and the second die comprise through silicon vias (TSVs).

Example 19: the method of Examples 11-18, wherein the first die and the second die are compute dies.

Example 20: the method of Examples 11-19, wherein the core has a thickness between approximately 50 μm and approximately 1,000 μm.

Example 21: an electronic package, comprising: a core with a first surface and a second surface opposite from the first surface, wherein the core comprises glass; through glass vias (TGVs) through the core; a first die and a second die attached to the core over the first surface; and a third die attached to the core over the second surface.

Example 22: the electronic package of Example 21, further comprising: buildup layers between the core and the first die and the second die, wherein the buildup layers comprise conductive routing to electrically couple the first die to the second die.

Example 23: the electronic package of Example 22, wherein a thickness of traces of the conductive routing is approximately 2 μm or less, and wherein a spacing between traces is approximately 2 μm or less.

Example 24: an electronic system, comprising: a board; and an electronic package coupled to the board, wherein the electronic package comprises: a core with a first surface and a second surface opposite from the first surface, wherein the core comprises glass; through glass vias (TGVs) through the core; buildup layers over the first surface of the core, wherein the buildup layers comprise traces; a first die and a second die attached to the traces, wherein the traces electrically couple the first die to the second die; and a third die attached to the core over the second surface.

Example 25: the electronic system of Example 24, wherein the traces have a thickness of approximately 2 μm or less, and wherein the traces have a spacing of approximately 2 μm or less.

Example 26: an electronic package, comprising: a core with a first surface and a second surface opposite from the first surface, wherein the core comprises glass; buildup layers over the first surface of the core, wherein the buildup layers comprise electrically conductive traces; a first die over the buildup layers; a second die over the buildup layers, wherein the first die is electrically coupled to the second die by the electrically conductive traces in the buildup layers; and a third die over the second surface of the core.

Example 27: the electronic package of Example 26, wherein through glass vias (TGVs) are provided through the core.

Example 28: the electronic package of Example 26 or Example 27, wherein the first die and the second die are compute dies, and wherein the third die is a memory die.

Example 29: the electronic package of Examples 26-28, wherein a width of the core is greater than a width of the third die.

Example 30: the electronic package of Examples 26-29, wherein the first die and the second die are embedded in a mold layer.

Example 31: the electronic package of Examples 26-30, wherein the electrically conductive traces comprise a trace width of approximately 2 μm or less and a trace spacing of approximately 2 μm or less.

Example 32: the electronic package of Examples 26-31, wherein the first die and the second die are coupled to the electrically conductive traces with hybrid bonding, solder, or micro balls.

Example 33: the electronic package of Examples 26-32, wherein the third die is bonded to the core by hybrid bonding, solder, or micro balls.

Example 34: the electronic package of Examples 26-33, wherein the first die and the second die comprise through silicon vias (TSVs).

Example 35: the electronic package of Examples 26-34, wherein the third die is coupled to the core without any buildup layers between the third die and the core.

Example 36: an electronic package, comprising: a core with a first surface and a second surface opposite from the first surface, wherein the core comprises glass; buildup layers over the first surface of the core, wherein the buildup layers comprise electrically conductive traces; a first die over the buildup layers; a second die over the buildup layers, wherein the first die is electrically coupled to the second die by the electrically conductive traces in the buildup layers; a third die over the second surface of the core; and exposed pads on the second surface of the core.

Example 37: the electronic package of Example 36, wherein wire bonds are coupled to the exposed pads.

Example 38: the electronic package of Example 36 or Example 37, further comprising: second buildup layers over the first die and the second die.

Example 39: the electronic package of Example 38, wherein conductive routing in the second buildup layers electrically couples the first die and the second die to second level interconnect (SLI) pads.

Example 40: the electronic package of Examples 36-39, wherein the first die and the second die are embedded in a mold layer.

Example 41: the electronic package of Examples 36-40, wherein through glass vias (TGVs) are provided through the core.

Example 42: the electronic package of Examples 36-41, wherein the first die and the second die are coupled to the electrically conductive traces by hybrid bonding, solder, or micro balls.

Example 43: the electronic package of Examples 36-42, wherein through silicon vias (TSVs) are provided through the first die and the second die.

Example 44: the electronic package of Examples 36-43, wherein the first die and the second die are compute dies, and wherein the third die is a memory die.

Example 45: the electronic package of Examples 36-44, wherein the electrically conductive traces have a trace thickness of approximately 2 μm or less, and a trace spacing of approximately 2 μm or less.

Example 46: an electronic package, comprising: a substrate with a first surface and a second surface opposite from the first surface, wherein the substrate comprises glass; through glass vias (TGVs) through the substrate; buildup layers over the first surface of the substrate; conductive traces in the buildup layers; a first die over the buildup layers; and a second die adjacent to the first die over the buildup layers, wherein the conductive traces electrically couple the first die to the second die.

Example 47: the electronic package of Example 46, further comprising: a third die over the second surface of the substrate.

Example 48: the electronic package of Example 47, wherein the first die and the second die are compute dies, and wherein the third die is a memory die.

Example 49: the electronic package of Example 47 or Example 48, further comprising: a board coupled to the second surface of the substrate, wherein the third die is surrounded by a cavity in the board.

Example 50: the electronic package of Examples 46-49, wherein the conductive traces include a trace width of approximately 2 μm or less and a trace spacing of approximately 2 μm or less.

Example 51: the electronic package of Examples 46-50, wherein the first die and the second die are coupled to the conductive traces by hybrid bonding, solder, or micro balls.

Example 52: the electronic package of Examples 46-51, wherein the TGVs are configured to route power from the first surface of the substrate to the second surface of the substrate.

Example 53: the electronic package of Examples 46-52, wherein the first die and the second die are embedded in a mold layer.

Example 54: the electronic package of Examples 46-53, wherein the first die and the second die comprise through silicon vias (TSVs).

Example 55: the electronic package of Examples 46-54, wherein the buildup layers comprise two or more buildup layers.

Example 56: an electronic package, comprising: a substrate with a first surface and a second surface opposite from the first surface, wherein the substrate comprises glass; buildup layers over the first surface of the substrate; a first die over the buildup layers; a second die over the buildup layers; and a bridge embedded in the buildup layers, wherein the bridge electrically couples the first die to the second die.

Example 57: the electronic package of Example 56, wherein the substrate comprises through glass vias (TGVs).

Example 58: the electronic package of Example 57, further comprising: a third die on the second surface of the substrate and coupled to one or more of the TGVs.

Example 59: the electronic package of Example 58, wherein the first die and the second die comprise compute dies, and wherein the third die comprises a memory die.

Example 60: the electronic package of Example 58 or Example 59, further comprising: a board coupled to the substrate, wherein the board comprises a cavity to accommodate the third die.

Example 61: the electronic package of Examples 57-59, wherein the TGVs have a trapezoidal shaped cross-section.

Example 62: the electronic package of Examples 56-61, wherein the first die and the second die are coupled to the bridge with hybrid bonding, solder, or micro balls.

Example 63: the electronic package of Examples 56-62, wherein the first die is a system on a chip (SoC), and the second die is a compute die.

Example 64: the electronic package of Examples 56-63, wherein a width of the substrate is greater than a combined width of the first die and the second die.

Example 65: the electronic package of Examples 56-64, wherein the bridge is within a footprint of both the first die and the second die.

Example 66: an electronic package, comprising: a first substrate, wherein the first substrate is an organic substrate; a second substrate over the first substrate, wherein the second substrate comprises glass; a first die on the second substrate; a second die on the second substrate adjacent to the first die; and conductive routing in the second substrate to electrically couple the first die to the second die.

Example 67: the electronic package of Example 66, wherein the first substrate is a package substrate.

Example 68: the electronic package of Example 66 or Example 67, wherein the first substrate is a board.

Example 69: the electronic package of Examples 66-68, wherein the second substrate comprises through glass vias (TGVs).

Example 70: the electronic package of Example 69, wherein the TGVs have an hourglass shaped cross-section.

Example 71: the electronic package of Examples 66-70, wherein the first die is a compute die and the second die is a memory die.

Example 72: the electronic package of Examples 66-71, wherein the conductive routing includes traces with a trace thickness of approximately 2 μm or less and a trace spacing of approximately 2 μm or less.

Example 73: the electronic package of Examples 66-72, wherein the first die and the second die are coupled to the conductive routing by hybrid bonding, solder, or micro balls.

Example 74: the electronic package of Examples 66-73, wherein a width of the first substrate is greater than a width of the second substrate.

Example 75: the electronic package of Examples 66-74, wherein the second substrate comprises a glass compatible with laser assisted patterning processes.

Example 76: an electronic package, comprising: a core, wherein the core comprises glass; buildup layers over the core; a first die over the buildup layers; a cavity through the core; and a second die in the cavity.

Example 77: the electronic package of Example 76, wherein the first die is a system on a chip (SoC), and the second die is a memory die.

Example 78: the electronic package of Example 76 or Example 77, further comprising: a third die and a fourth die in the cavity.

Example 79: the electronic package of Example 78, wherein the second die, the third die, and the fourth die are stacked vertically.

Example 80: the electronic package of Example 79, wherein a total thickness of the second die, the third die, and the fourth die is greater than a thickness of the core.

Example 81: the electronic package of Examples 76-80, wherein through glass vias (TGVs) are provided through the core.

Example 82: the electronic package of Examples 76-81, wherein the core has a thickness between approximately 50 μm and approximately 1,000 μm.

Example 83: the electronic package of Examples 76-82, further comprising: second buildup layers below the core.

Example 84: the electronic package of Examples 76-83, wherein the first die is electrically coupled to the second die through conductive routing in the buildup layers.

Example 85: the electronic package of Examples 76-84, wherein the second die is outside of a footprint of the first die.

Example 86: an electronic package, comprising: buildup layers, wherein the buildup layers comprise an organic material; conductive routing in the buildup layers, where the conductive routing comprises traces with a trace width of approximately 2 μm or less and a trace spacing of approximately 2 μm or less; a first die over the buildup layers; and a second die over the buildup layers, wherein the first die is electrically coupled to the second die by the conductive routing.

Example 87: the electronic package of Example 86, wherein the first die and the second die comprise compute dies.

Example 88: the electronic package of Example 86 or Example 87, wherein the first die and the second die comprise through silicon vias (TSVs).

Example 89: the electronic package of Example 88, further comprising: second buildup layers over the first die and the second die, wherein the second buildup layers comprise electrical routing to couple the TSVs to second level interconnect (SLI) pads.

Example 90: the electronic package of Examples 86-89, wherein the first die and the second die are embedded in a mold layer.

Example 91: the electronic package of Examples 86-90, wherein a bottommost layer of the conductive routing is above a bottom surface of the buildup layers.

Example 92: the electronic package of Examples 86-91, wherein the buildup layers comprises three or more layers.

Example 93: the electronic package of Examples 86-92, wherein the first die and the second die are coupled to the conductive routing by hybrid bonding, solder, or micro balls.

Example 94: a method of forming an electronic package, comprising: forming conductive routing in first buildup layers formed over a carrier, wherein the conductive routing has a trace width of approximately 2 μm or less and a trace spacing of approximately 2 μm or less; attaching a first die and a second die to the conductive routing; forming a mold layer around the first die and the second die; forming second buildup layers over the first die and the second die; and removing the carrier.

Example 95: the method of Example 94, wherein the carrier comprises glass.

Example 96: the method of Example 94 or Example 95, wherein the first die and the second die comprise through silicon vias (TSVs).

Example 97: the method of Examples 94-96, wherein the first die and the second die are coupled to the conductive routing with hybrid bonding, solder, or micro balls.

Example 98: the method of Examples 94-97, wherein the first die and the second die are compute dies.

Example 99: the method of Examples 94-98, wherein the second buildup layers end at a second level interconnect (SLI) pad.

Example 100: the method of Examples 94-99, wherein removing the carrier is done with a depaneling process.

What is claimed is:

1. An electronic package, comprising:
a substrate, wherein the substrate comprises glass;
buildup layers over the first substrate;
a first die over the buildup layers;
a second die over the buildup layers and adjacent to the first die, and wherein conductive routing in the buildup layers electrically couples the first die to the second die.

2. The electronic package of claim 1, wherein the conductive routing includes traces with a line thickness of approximately 2 μm or less and a line spacing of approximately 2 μm or less.

3. The electronic package of claim 1, wherein the first die and the second die comprise through silicon vias (TSVs).

4. The electronic package of claim 3, further comprising:
second buildup layers over the first die and the second die, wherein the TSVs are coupled to pads on a surface of the second buildup layers.

5. The electronic package of claim 1, further comprising:
a third die on an opposite surface of the substrate from the first die and the second die.

6. The electronic package of claim 5, wherein the third die is a memory die.

7. The electronic package of claim 5, wherein through glass vias (TGVs) are provided through the substrate.

8. The electronic package of claim 1, wherein a mold layer is provided around the first die and the second die.

9. The electronic package of claim 1, wherein the first die and the second die are compute dies.

10. The electronic package of claim 1, wherein the substrate has a thickness that is between approximately 50 μm and approximately 1,000 μm.

11. A method of forming an electronic package, comprising:
forming through glass vias (TGVs) through a core comprising glass;
forming first buildup layers over the core, wherein the first buildup layers comprise routing with line/space dimensions of approximately 2 μm/2 μm or less;
forming second buildup layers over the core opposite from the first buildup layers;
attaching a first die and a second die to the routing in the first buildup layers;
forming a mold layer around the first die and the second die; and
forming third buildup layers over the mold layer.

12. The method of claim 11, wherein the first die and the second die are attached to the routing in the first buildup layer with hybrid bonding.

13. The method of claim 11, wherein the first die and the second die are attached to the routing in the first buildup layer with solder.

14. The method of claim 11, wherein the first die and the second die are attached to the routing in the first buildup layer with micro balls.

15. The method of claim 11, further comprising:
attaching a third die to routing in the second buildup layers.

16. The method of claim 15, wherein the third die is a memory die.

17. The method of claim 15, wherein the third die is embedded in a second mold layer.

18. The method of claim 11, wherein the first die and the second die comprise through silicon vias (TSVs).

19. The method of claim 11, wherein the first die and the second die are compute dies.

20. The method of claim 11, wherein the core has a thickness between approximately 50 μm and approximately 1,000 μm.

21. An electronic package, comprising:
a core with a first surface and a second surface opposite from the first surface, wherein the core comprises glass;
through glass vias (TGVs) through the core;
a first die and a second die attached to the core over the first surface; and
a third die attached to the core over the second surface.

22. The electronic package of claim 21, further comprising:
buildup layers between the core and the first die and the second die, wherein the buildup layers comprise conductive routing to electrically couple the first die to the second die.

23. The electronic package of claim 22, wherein a thickness of traces of the conductive routing is approximately 2 μm or less, and wherein a spacing between traces is approximately 2 μm or less.

24. An electronic system, comprising:
a board; and
an electronic package coupled to the board, wherein the electronic package comprises:
a core with a first surface and a second surface opposite from the first surface, wherein the core comprises glass;
through glass vias (TGVs) through the core;
buildup layers over the first surface of the core, wherein the buildup layers comprise traces;
a first die and a second die attached to the traces, wherein the traces electrically couple the first die to the second die; and
a third die attached to the core over the second surface.

25. The electronic system of claim 24, wherein the traces have a thickness of approximately 2 μm or less, and wherein the traces have a spacing of approximately 2 μm or less.
